(19) United States
(12) Patent Application Publication
(10) Pub. No.: US 2026/0285608 A1
(43) Pub. Date: Sep. 24, 2026

(54) HIGH-VOLUME PRODUCTION LINE

(71) Applicant: ASMPT SMT Singapore Pte. Ltd., Singapore (SG)

(72) Inventor: Simon LANCASTER, Weymouth (GB)

(21) Appl. No.: 19/570,642

(22) Filed: Mar. 18, 2026

(30) Foreign Application Priority Data
Mar. 19, 2025 (GB) 2503969.4

(51) Int. Cl. B65G 37/02; H05K 13/00

(52) U.S. Cl. CPC B65G 37/02; H05K 13/0061

(57) ABSTRACT

A production line for processing a workpieces, comprising a plurality of loops located in series along a main conveyor, each loop branching from the main conveyor line via a respective branching conveyor located at a relatively upstream location of the main conveyor line and returning to a relatively downstream location of the main conveyor line via a respective return conveyor, and each loop comprising a respective processing module located between the respective branching conveyor and return conveyor, such that a workpiece may be diverted from the main conveyor line to a loop via its respective branching conveyor, be processed by its respective processing module and returned to the main conveyor line via its respective return conveyor, wherein, when the number of operational loops, an operational loop being a loop in which the respective conveyors and processing module are all fully operational, is X, where X is an integer greater than 1, the control means is configured such that during an operational phase of the production line each branching conveyor of an operational loop diverts every Xth workpiece received at that respective branching conveyor away from the main conveyor line to its respective loop, so that each of the processing modules operate at maximised capacity.

This invention relates to a production line for processing workpieces and a method of processing workpieces.

### BACKGROUND AND PRIOR ART

A typical production line for processing workpieces may comprise a plurality of processing modules arranged in series along a conveyor line, along which the workpieces are sequentially conveyed.

Such a production line 1 is schematically shown in FIG. 1. Here, a succession of workpieces (not shown) are fed to an input 2 one after the other. The production line 1 includes a plurality (here three) of processing modules for processing the workpieces in some known way. For example, each processing module may comprise a printing machine 4 for printing conductive paste onto a workpiece such as a fuel cell board. A number of conveyors 5 are used to transport workpieces from the input 2 to an output 3 via each of the printing machines 4, which can be put into a “pass-through” mode in which already processed workpieces can simply move through the printing machine without undergoing further processing.

It can readily be seen that such a production line is inefficient. In particular, the printing machines 4 cannot all operate continuously, and so operate nowhere near their theoretical maximum capacity. In addition, if, for example, an element of the production line 1 fails, for example a conveyor 5 between two printing machines 4, then the entire production line 1 will halt.

FIG. 2 schematically shows an alternative production line, in which the same number of printing machines 4, i.e. three, are provided, but this time arranged in a parallel arrangement between the input 2 and output 3. Here, workpieces received at the input 2 are directed to one of the three printing machines 4, for example the first, fourth, seventh etc workpieces may be directed to the topmost-shown printing machine 4, the second, fifth, eighth etc workpiece may be directed to the middle printing machine 4, while the third, sixth, ninth etc workpiece may be directed to the lowest-shown printing machine 4. This arrangement may permit the printing machines to operate at a higher capacity, and also permits the production line to continue if, for example, one of the printing machines 4 fails. However, such an arrangement is practically difficult to achieve, and in particular this arrangement makes it difficult for an operator or robot to access the middle printing machine, since it is effectively surrounded by conveyors and other printing machines.

The present invention seeks to provide an improved production line and method for processing workpieces, which enables workpieces to be processed at or near maximum capacity, while being responsive to faults occurring within the line, and retaining access to the processing modules.

In accordance with the present invention this aim is achieved through the use of a looped arrangement, with a processing module provided on each loop, and controlling the order in which workpieces are sent to respective loops.

### SUMMARY OF THE INVENTION

In accordance with a first aspect of the present invention there is provided a production line for processing a workpieces, comprising:
a control means,
an input arranged to receive, in a sequential fashion, a plurality of workpieces which are unprocessed,
an output arranged to output, in a sequential fashion, the workpieces following processing,
a main conveyor line directly connecting the input and the output, arranged such that a workpiece may travel directly downstream along the main conveyor line from the input to the output,
a plurality of loops located in series along the main conveyor line, each loop branching from the main conveyor line via a respective branching conveyor located at a relatively upstream location of the main conveyor line and returning to a relatively downstream location of the main conveyor line via a respective return conveyor, and each loop comprising a respective processing module located between the respective branching conveyor and return conveyor, such that a workpiece may be diverted from the main conveyor line to a loop via its respective branching conveyor, be processed by its respective processing module and returned to the main conveyor line via its respective return conveyor,
wherein, when the number of operational loops, an operational loop being a loop in which the respective conveyors and processing module are all fully operational, is X, where X is an integer greater than 1, the control means is configured such that during an operational phase of the production line each branching conveyor of an operational loop diverts every Xth workpiece received at that respective branching conveyor away from the main conveyor line to its respective loop, so that each of the processing modules operate at maximised capacity.

In accordance with a second aspect of the present invention there is provided a method of processing workpieces, comprising the steps of:
i) providing a production line, the production line comprising:
   a control means,
   an input,
   an output,
   a main conveyor line directly connecting the input and the output arranged such that a workpiece may travel directly downstream along the main conveyor line from the input to the output,
   a plurality of loops located in series along the main conveyor, each loop branching from the main conveyor line via a respective branching conveyor located at a relatively upstream location of the main conveyor line and returning to a relatively downstream location of the main conveyor line via a respective return conveyor, and each loop comprising a respective processing module located between the respective branching conveyor and return conveyor, such that a workpiece may be diverted from the main conveyor line to a loop via its respective branching conveyor, be processed by its respective processing module and returned to the main conveyor line via its respective return conveyor;
ii) determining the number X of loops which are operational loops, an operational loop being a loop in which the respective conveyors and processing module are all fully operational, where X is an integer greater than 1;
iii) commencing a set-up phase by commencing to convey the plurality of unprocessed workpieces to the input in a sequential fashion, and thereafter onto the main conveyor line;
iv) completing the set-up phase by diverting workpieces from the main conveyor line so that each operational loop has at least one workpiece located thereon;
V) commencing an operational phase comprising controlling the branching conveyors so that each branching conveyor diverts every Xth workpiece received at that respective branching conveyor away from the main conveyor line to its respective operational loop; vi) processing workpieces received at respective processing modules;
vii) returning the processed workpieces to the main conveyor line; and
viii) conveying the processed workpieces to the output.

Other specific aspects and features of the present invention are set out in the accompanying claims.

### BRIEF DESCRIPTION OF THE DRAWINGS

The invention will now be described with reference to the accompanying drawings (not to scale), in which:

FIG. 1 schematically shows an exemplary known “series-connected” production line;

FIG. 2 schematically shows an exemplary known “parallel-connected” production line;

FIG. 3 schematically shows a production line in accordance with the present invention;

FIGS. 4 to 12 schematically show the production line of FIG. 3 during an initial set-up phase;

FIGS. 13 and 14 schematically show the production line of FIG. 3 during an operational phase; and

FIG. 15 schematically shows the production line of FIG. 14 following development of a fault.

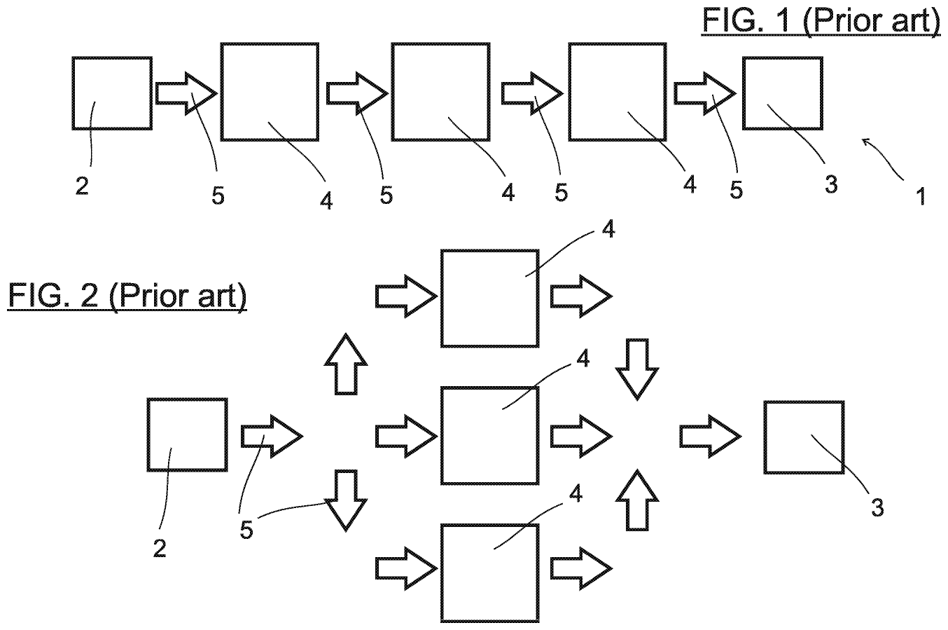

As far as possible, similar components of the apparatus shown will retain like reference numerals throughout the Figures.

### DETAILED DESCRIPTION OF THE PREFERRED EMBODIMENTS OF THE INVENTION

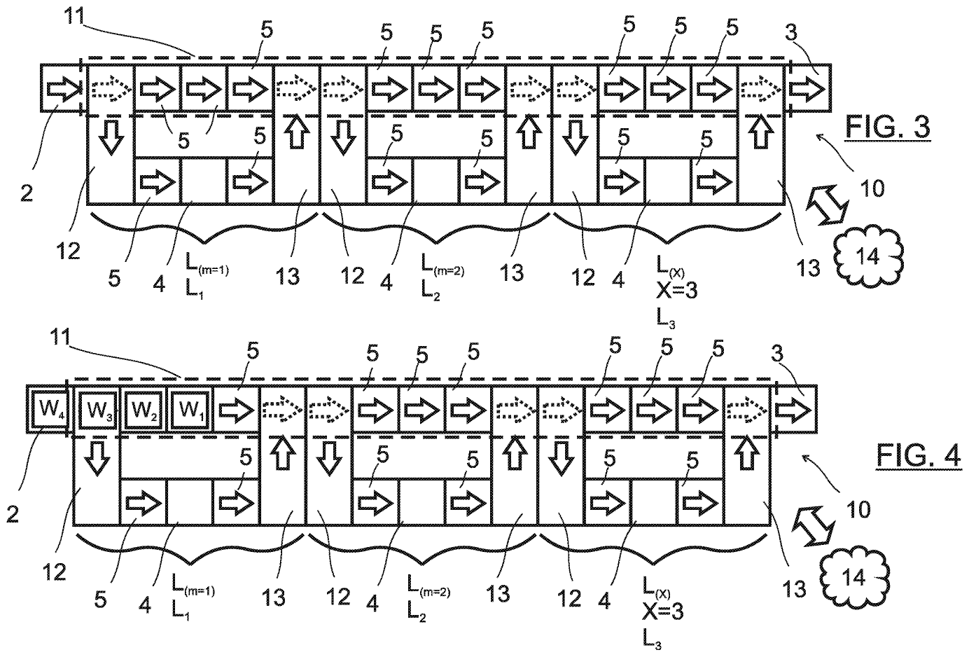

A production line 10 in accordance with the present invention is schematically shown in FIG. 3, in which the flow of workpieces (not shown in FIG. 3), i.e. the ‘downstream’ direction, is generally from left to right as shown. An input 2 is arranged at the most upstream location to receive the workpieces in a sequential fashion, which workpieces are unprocessed. An output 3 is arranged at the most downstream location to output, in a sequential fashion, the workpieces following their processing. A main conveyor line 11 directly connects the input 2 and output 3. The main conveyor comprises a plurality of individual conveyors 5 arranged such that a workpiece may travel directly downstream along the main conveyor line 11 from the input 2 to the output 3, without passing any processing modules 4, although in use this will only be caused to happen if a workpiece is identified as being defective and so not useful to process. The production line 10 includes a plurality of loops L located in series along the main conveyor line 11. Each loop L branches from the main conveyor line 11 via a respective branching conveyor 12 located at a relatively upstream location of the main conveyor line 11, and returns to a relatively downstream location of the main conveyor line 11 via a respective return conveyor 13. Each branching conveyor 12 is operable to selectively divert a workpiece arriving thereat from the main conveyor line 11 away from the main conveyor line 11, and onto the respective loop towards the respective processing module 4. Workpieces which are not so diverted may proceed downstream along the main conveyor line 11, i.e. from left to right as shown. Each return conveyor 13 acts as a funnel so that workpieces arriving from its respective loop are replaced onto the main conveyor line, to continue transport downstream, i.e. from left to right as shown. Suitable branching and return conveyors are well-known in the art per se, and so need not be described in detail here. Each loop further comprises a respective processing module 4 located between the respective branching conveyor 12 and respective return conveyor 13. In this way, a workpiece may be diverted from the main conveyor line 11 to a loop via its respective branching conveyor 12, be processed by its respective processing module 4 and returned to the main conveyor line 11 via its respective return conveyor 13. As can be seen in FIG. 3, each loop may also comprise individual conveyors 5, here located proximate the processing module 4 on both upstream and downstream sides. The entire production line 10 is controlled by a control means 14, which may comprise a computer or analogous processing means, running software or embodied in hardware, located at the production line 10 or remote therefrom, for example a cloud or network-based control means, and operable to communicate with and thereby control the various conveyors 5, 12, 13 and processing modules 4 of the production line 10. Advantageously, the control means 14 is also operative to detect faults occurring within the production line and take restorative or mitigating action if required, as will be described in more detail below.

It can be seen that with this set-up of production line 10, all of the processing modules 4 are accessible, either by a human operator or a robot, greatly facilitating repair and replenishment.

To fully describe the operation of the production line 10, it is necessary to unambiguously identify the various loops present in the production line 10. Throughout this document, the number of operational loops will be given assigned the value X, where X is an integer greater than 1. Here, the term “operational loop” means a loop in which its respective conveyors and processing module are all fully operational. At this stage, and for clarity, it shall be assumed that all of the loops in the production line 10 of FIG. 3 are operational. Therefore, for the production line 10 shown, X=3. The operational loops may then be respectively incrementally designated

$${( L m )}_{m = 1}^{X}$$

where Lₘ where L and m are positive integers, such that each operational loop is designated L₁ to Lx increasing in the downstream direction. In FIG. 3, which has three operational loops, the loops are therefore designated L₁, L₂ and L₃ as shown. While for convenience the production line 10 has three loops, the invention is not so limited, and theoretically any number of loops greater than 1 may be provided along the main conveyor line 11.

Similarly, it is necessary to unambiguously identify the various workpieces which pass through the production line 10. The workpieces are therefore incrementally designated

$${( W n )}_{n = 1}^{∞}$$

where n is a positive integer. The first workpiece entering the production line 10 will thereby be designated W₁, the second W₂ etc.

In accordance with the present invention, the control means 14 is configured such that during an operational phase of the production line 10, each branching conveyor 12 of an operational loop diverts every Xth workpiece received at that respective branching conveyor 12 away from the main conveyor line 11 to its respective loop, so that each of the processing modules 4 operate at maximised capacity. For example, for the production line 10 shown in FIG. 3 where X=3, each branching conveyor 12 diverts every 3^{rd} workpiece received at that branching conveyor.

The operational phase is a “steady-state” phase which should form the bulk of the total operating time of the production line 10, and will occur after completion of a “set-up phase” in which all operational loops are loaded with workpieces, which will be necessary when the production line 10 commences production, or following a reconfiguration, for example in the event of a detected fault occurring in the production line 10.

An initial set-up phase is schematically shown in FIGS. 4 to 12.

FIG. 4 shows the production line 10 immediately after with the first four workpieces Wₙ have been fed to the production line 10. At this stage, all of the first three workpieces W₁, W₂, W₃ are located on the main conveyor line 11, with the fourth workpiece W₄ positioned at the input 2.

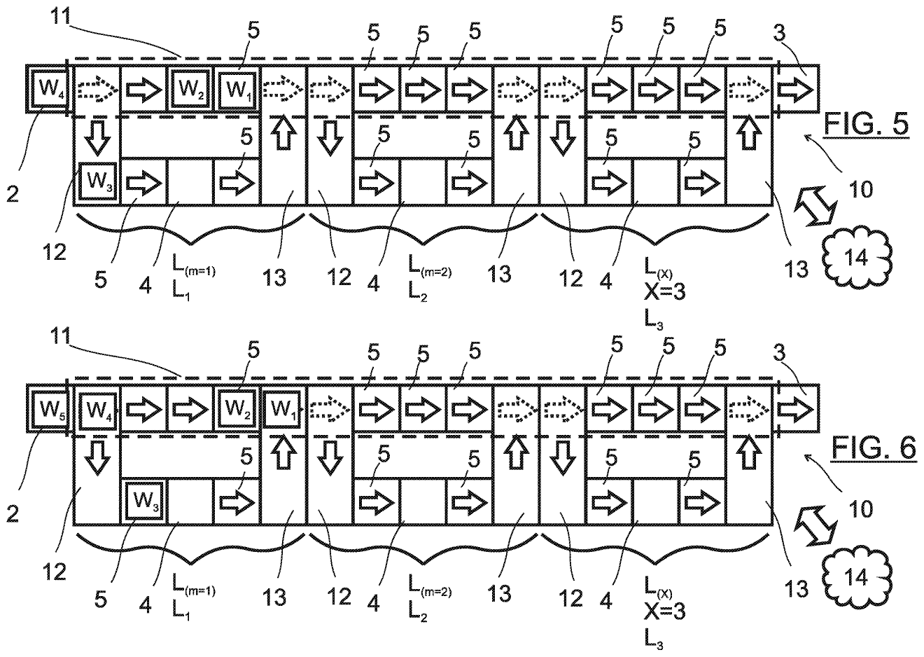

FIG. 5 shows an immediately subsequent stage, in which the third workpiece W₃ is diverted by the branching conveyor 12 associated with the first loop L₁ onto that first loop L₁. During the diversion, the first and second workpieces W₁, W₂ can progress along the main conveyor line 11, but the fourth workpiece W₄ is forced to remain at the input 2 until the diversion has been completed.

As shown in FIG. 6, following the diversion of the third workpiece W₃, the fourth workpiece W₄ may continue along the main conveyor line 11, and the next, fifth, workpiece W₅ may arrive at input 2. The first two workpieces W₁, W₂ may also continue along the main conveyor line 11.

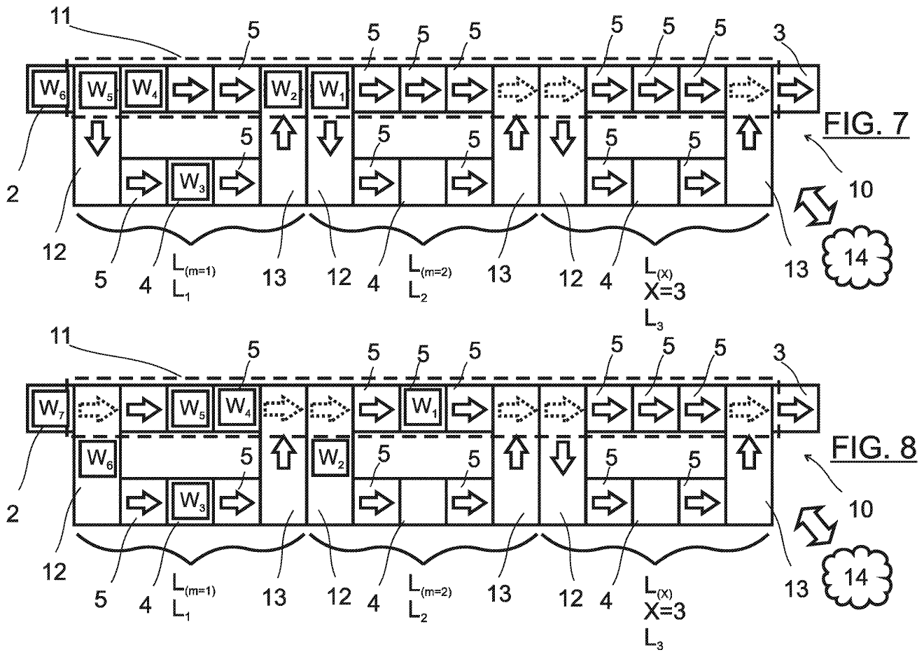

As shown in FIG. 7, workpieces W₁, W₂, W₄ and W₅ progress along the main conveyor line 11, and a subsequent workpiece We is fed to the input 2. Workpiece W₃ arrives at the processing module 4 of the first loop L₁, and processing thereof commences. The processing takes longer than the conveyance time across a conveyor 5. The production line 10 is therefore preferably arranged so that the time taken for a workpiece to travel between the branching and return conveyors 12, 13 associated with a single loop L is approximately the time taken to process a workpiece. This is achieved by choosing lengths and controlling the required speeds of conveyors 5 which match this optimum profile.

FIG. 8 shows a subsequent stage in the set-up phase. Workpiece W₃ has not yet completed its processing, but the other workpieces can proceed along the production line 10, with the next workpiece W₇ being fed to the input 2. The second workpiece W₂ is diverted by the branching conveyor of the second loop L₂, and the sixth workpiece We is diverted by the branching conveyor 12 of the first loop L₁.

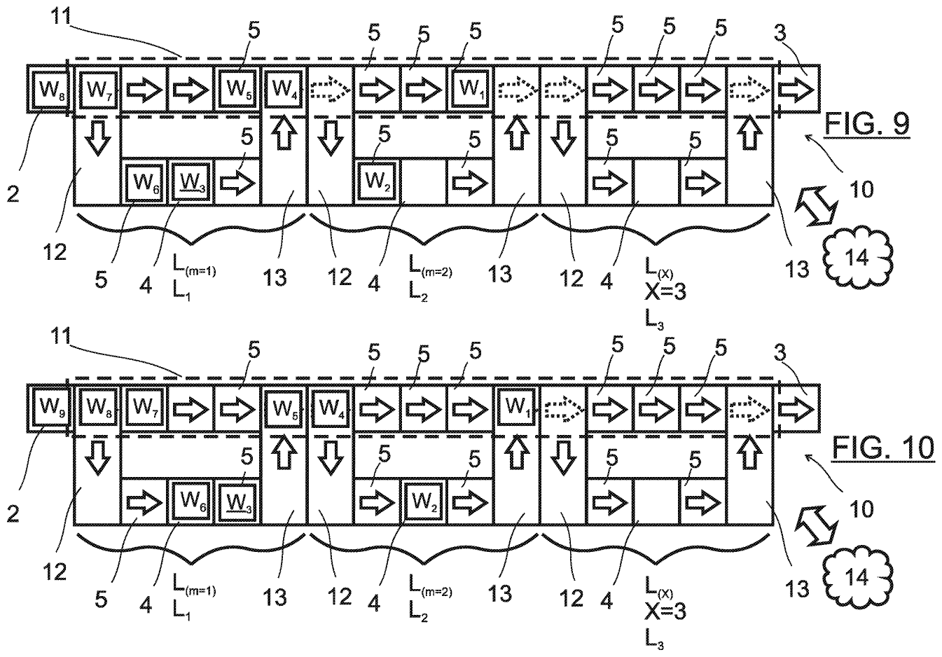

In FIG. 9, the third workpiece W₃ finishes its processing. For clarity, henceforth processed workpieces will be shown with the ‘W’ underlined. By this time, workpiece We has reached the processing module 4 of the first loop L₁, ready to take the place of workpiece W₃. Synchronously, the second workpiece W₂ reaches the processing module 4 of the second loop L₂.

In FIG. 10, workpiece We replaces workpiece W₃ within the processing module 4 of the first loop L₁ and commences its processing, synchronously to workpiece W₂ entering the processing module 4 of the second loop L₂ for processing. The other workpieces proceed along the main conveyor line 11.

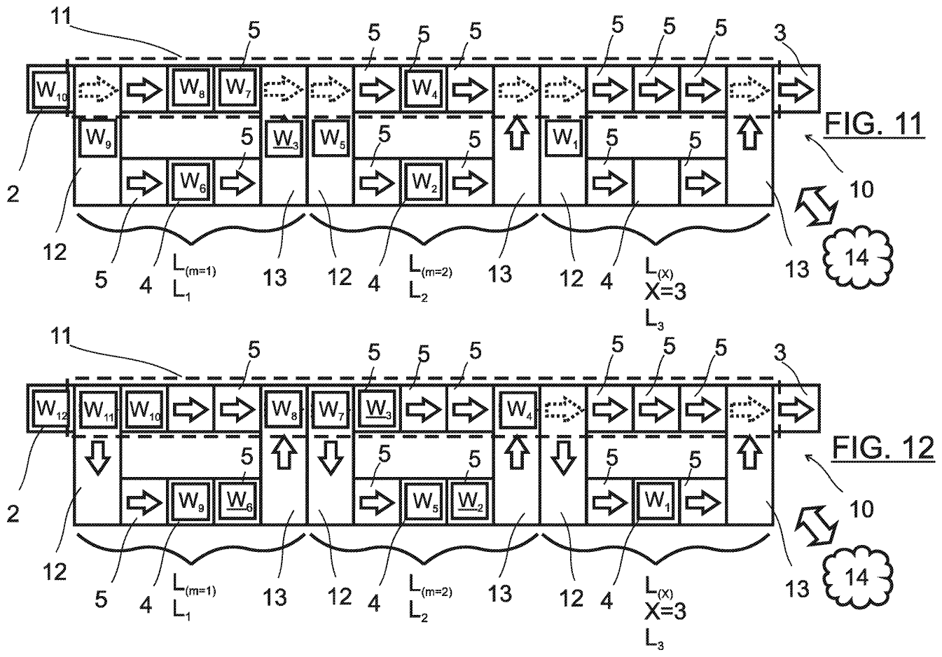

In FIG. 11, workpieces W₂ and We continue their processing, while processed workpiece W₃ returns to the main conveyor line 11 by the return conveyor 13 of the first loop L₁. The conveyor 5 directly upstream on the main conveyor line 11, which currently has workpiece W₇ located thereon, is locked from operation to enable the return conveyor 13 to return workpiece W₃ to the main conveyor line 11. Such locking will occur whenever a directly downstream return conveyor 13 is returning a workpiece to the main conveyor line 11. Workpieces W₁, W₅ and W₉ meanwhile are synchronously diverted away from the main conveyor line 11 by the branching conveyors 12 of the third, second and first loops respectively.

FIG. 12 represents the end of the set-up phase, and the start of the operational phase. The operational phase can commence when all of the processing modules 4 of all X loops are occupied, as shown.

As noted above, during the operational phase, the control means 14 is configured such that each branching conveyor 12 of an operational loop diverts every Xth workpiece received at that respective branching conveyor 12 away from the main conveyor line 11 to its respective loop, so that each of the processing modules 4 operate at maximised capacity, and as shown, this will be every 3^{rd} workpiece.

This operation can be defined more exactly in a number of ways. In particular, during the operational phase the branching conveyors 12 may be controlled by the control means 14 to divert only certain workpieces received thereat, which workpieces are designated Wₙ where n=kX−m+1, where k is a positive integer in the sequence k₁=1, k₂=2, k₃=3, . . . , to its respective operational loop, and not to divert any workpiece which is not so designated.

This may alternatively be expressed such that, in the operational phase (and indeed also in the initial set-up phase), the control system is configured to operate the branching conveyors 12 to divert each workpiece Wₙ to a loop Lₘ only where

$$m = - ( ( ( n + 2 X - 1 ) mod X ) - X )$$

So, for a system as shown where X=3, the workpieces will be diverted as follows, noting that as shown, workpieces W₁ to W₃, W₅, We and We are diverted during the set-up phase:

TABLE 1
Workpiece processing where X = 3

| Workpiece | Diverted to Loop |
|---|---|
| W₁ | L₃ (set-up phase) |
| W₂ | L₂ (set-up phase) |
| W₃ | L₁ (set-up phase) |
| W₄ | L₃ |
| W₅ | L₂ (set-up phase) |
| W₆ | L₁ (set-up phase) |
| W₇ | L₃ |
| W₈ | L₂ |
| W₉ | L₁ (set-up phase) |
| W₁₀ | L₃ |
| W₁₁ | L₂ |
| W₁₂ | L₁ |
| W₁₃ | L₃ |
| W₁₄ | L₂ |
| W₁₅ | L₁ |

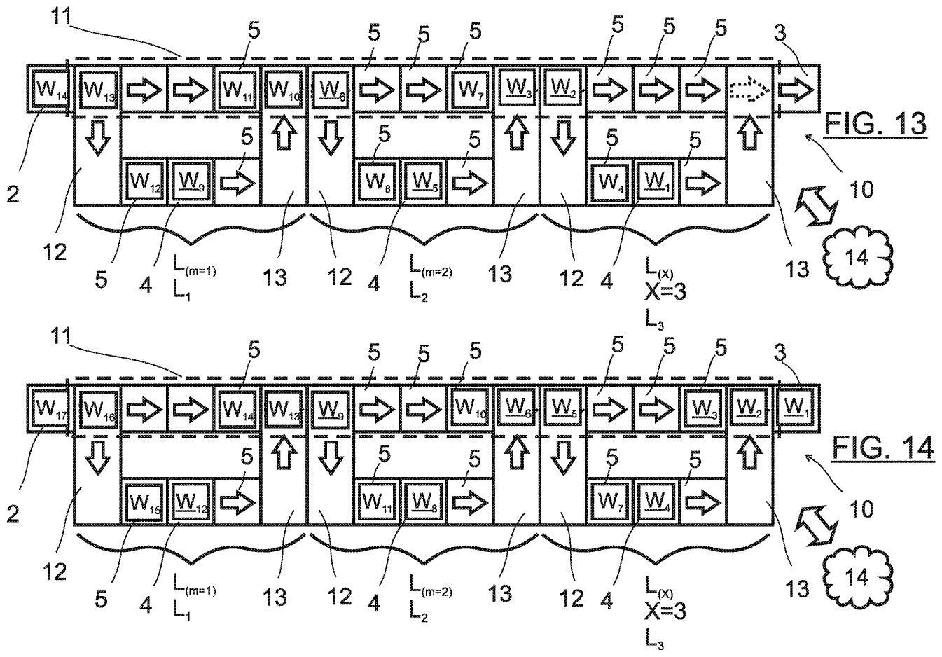

FIG. 13 shows a subsequent stage of operation following commencement of the operational phase, with the relevant workpieces being diverted as set out above. It can be seen that all of the processing modules 4 are occupied, and also have a workpiece directly upstream of them, ready to enter the respective processing module 4 once the workpiece being currently processed departs. Therefore, during the operational phase, all of the process modules 4 are operating at maximum capacity.

FIG. 14 shows a subsequent stage of the operational phase, which is chosen to illustrate that, when the control means 14 operates the conveyors of the main conveyor line 11 and the operational loops L as set out above, the processed workpieces arrive at the output 3 in the same order as the unprocessed workpieces are received at the input 2. As shown therefore, workpiece W₁ arrives at the output 3 first, followed by workpiece W₂ and then workpiece W₃. Workpiece W₄ is shown undergoing processing, but will arrive at the output 3 after workpiece W₃, and so on.

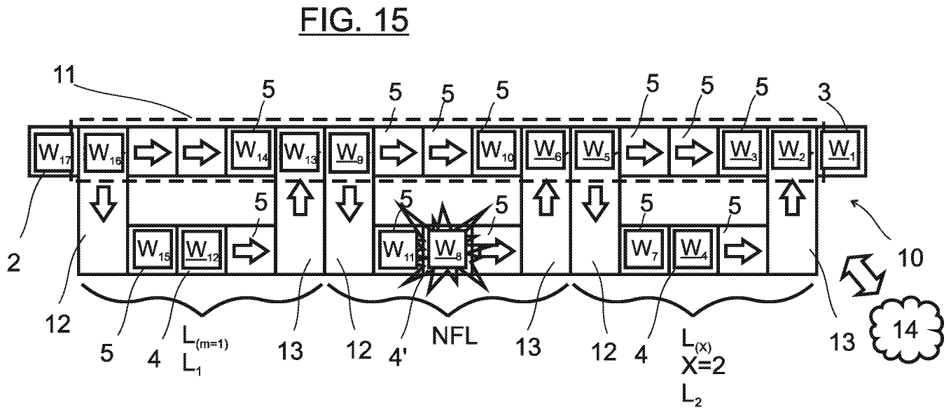

It can therefore be seen that the production line 10 is operationally efficient, while permitting operator access to the processing modules 4. Another advantage of the production line 10 is its flexibility, and the capacity to adapt to changes in operating efficiency. An example of this flexibility will now be described with reference to FIG. 15.

FIG. 15 shows the production line 10 in the state shown in FIG. 14, however the processing module of the second loop (henceforth denoted 4′) has become inoperable. For example, if the processing module 4′ is a printing machine for fuel cell boards, then the printing machine 4′ may have run out of a consumable material such as solder paste or cleaning material, or the printing material has become unsuitable for printing, etc. Such a problem is detected by the control means 14. In this case, the second loop becomes non-functional, and is henceforth denoted “NFL”. X will therefore drop to X=2, and the rightmost loop shown will be designated L₂. With these new parameters, the optimum operational phase would process workpieces as follows:

TABLE 2
Idealised workpiece processing where X = 2

| Workpiece | Diverted to Loop |
|---|---|
| W₁ | L₂ |
| W₂ | L₁ |
| W₃ | L₂ |
| W₄ | L₁ |
| W₅ | L₂ |
| W₆ | L₁ |
| W₇ | L₂ |
| W₈ | L₁ |
| W₉ | L₂ |
| W₁₀ | L₁ |
| W₁₁ | L₂ |
| W₁₂ | L₁ |
| W₁₃ | L₂ |
| W₁₄ | L₁ |
| W₁₅ | L₂ |

i.e., alternate workpieces are diverted to and processed by alternate loops.

It is necessary for the control means 14 to place the production line 10 in a type of set-up phase, in this case a ‘reconfiguring set-up phase’, to move the production line 10 towards this idealised operational phase.

In this reconfiguration set-up phase, no workpieces are directed to the NFL. Any unprocessed workpieces, such as workpiece W₁₀, present on the main conveyor line adjacent the NFL, may be passed to the loop L₂ for processing, regardless of their designation to ensure that all workpieces are processed before exiting the production line 10. If the processing module 4′ is still operable to pass-through workpieces, then unprocessed workpieces present on the NFL, such as workpiece W₁₁, may be conveyed to the main conveyer line 11, and then onto a functioning loop, i.e. L₂ in this case. Immediately upstream conveyors 5 may be locked to enable the return of such workpieces via the respective return conveyors 13. Processed workpieces on the NFL, such as W₈, may be returned to the main conveyor line 11 and conveyed to the output 3 in the usual way. If however the nature of the fault is such that transport along the NFL is impossible, for example a conveyor has developed a fault, then any workpieces present on the NFL upstream of that fault will remain there until the fault can be rectified. Depending on the nature of the fault and the state of the production line 10 when the fault occurs, it might not be possible to send processed workpieces to the output 3 in the same order that they were received at input 2. While this is disadvantageous, it is not overly problematic as long as the control means 14 is able to track the locations of the workpieces, or if the workpieces are individually marked, e.g. by a barcode, QR code or the like, and subsequently identified.

When the fault is rectified, this is detected by the control means 14. This may then instigate a new reconfiguration set-up phase to return the production line 10 to its optimal operational phase, where X=3.

The above-described embodiments are exemplary only, and other possibilities and alternatives within the scope of the invention will be apparent to those skilled in the art. For example, the number of loops present need not be 3, but could be any positive integer greater than 1.

The present invention has been described with particular reference to a production line for printing fuel cell boards, but is not so limited.

### REFERENCE NUMERALS USED

1, 10—Production line
2—Input
3—Output
4—Processing module
4′—Non-operational processing module
5—Conveyor
11—Main conveyor line
12—Branching conveyor
13—Return conveyor
14—Control means
L—Loop
NFL—Non-functional loop

1. A production line for processing a workpieces, comprising:
a control means,
an input arranged to receive, in a sequential fashion, a plurality of workpieces which are unprocessed,
an output arranged to output, in a sequential fashion, the workpieces following processing,
a main conveyor line directly connecting the input and the output, arranged such that a workpiece may travel directly downstream along the main conveyor line from the input to the output,
a plurality of loops located in series along the main conveyor, each loop branching from the main conveyor line via a respective branching conveyor located at a relatively upstream location of the main conveyor line and returning to a relatively downstream location of the main conveyor line via a respective return conveyor, and each loop comprising a respective processing module located between the respective branching conveyor and return conveyor, such that a workpiece may be diverted from the main conveyor line to a loop via its respective branching conveyor, be processed by its respective processing module and returned to the main conveyor line via its respective return conveyor,
wherein, when the number of operational loops, an operational loop being a loop in which the respective conveyors and processing module are all fully operational, is X, where X is an integer greater than 1, the control means is configured such that during an operational phase of the production line each branching conveyor of an operational loop diverts every Xth workpiece received at that respective branching conveyor away from the main conveyor line to its respective loop, so that each of the processing modules operate at maximised capacity.

2. The production line of claim 1, wherein the control means is configured to commence the operational phase following a set-up phase in which all operational loops are provided with at least one workpiece for processing.

3. The production line of claim 2, wherein the control means is configured to commence a set-up phase if it is determined that the number of operational loops, and hence X, in the production line changes.

4. The production line of claim 1, wherein the control means is configured to operate all branching conveyors associated with operational loops synchronously.

5. The production line of claim 4, wherein the control means is configured to operate all return conveyors associated with operational loops synchronously with the branching conveyors.

6. The production line of claim 1, wherein the plurality of workpieces may be incrementally designated
$${( W n )}_{n = 1}^{∞}$$
where n is a positive integer.

7. The production line of claim 6, wherein the branching conveyor associated with an mth loop, (where m=1 to X incrementally increasing in the downstream direction) is configured to divert every workpiece received thereat which is designated Wₙ where n=kX−m+1, where k is a positive integer in the sequence k₁=1, k₂=2, k₃=3, . . . , to its respective operational loop, and not to divert any workpiece which is not so designated.

8. The production line of claim 6, wherein the operational loops are respectively incrementally designated
$${( L m )}_{m = 1}^{X}$$
where Lₘ where L is a positive integer,
and wherein the control system is configured to operate the branching conveyors to divert each workpiece Wₙ to a loop Lₘ only where m=−(((n+2X−1)modX)−X).

9. The production line of claim 1, wherein the control means is configured to control operation of conveyors of the main conveyor line and the operational loops such that workpieces arrive at the output in the same order as they are received at the input.

10. The production line of claim 1, which is configured such that the time taken for a workpiece to travel between the branching and return conveyors associated with a single loop L is approximately the time taken to process a workpiece by a processing module.

11. The production line of claim 1, wherein each processing module comprises a printing machine.

12. The production line of claim 1, wherein each workpiece comprises a fuel cell substrate.

13. A method of processing workpieces, comprising the steps of:
i) providing a production line, the production line comprising:
a control means,
an input,
an output,
a main conveyor line directly connecting the input and the output arranged such that a workpiece may travel directly downstream along the main conveyor line from the input to the output,
a plurality of loops located in series along the main conveyor, each loop branching from the main conveyor via a respective branching conveyor located at a relatively upstream location of the main conveyor line and returning to a relatively downstream location of the main conveyor line via a respective return conveyor, and each loop comprising a respective processing module located between the respective branching conveyor and return conveyor, such that a workpiece may be diverted from the main conveyor line to a loop via its respective branching conveyor, be processed by its respective processing module and returned to the main conveyor line via its respective return conveyor;
ii) determining the number X of loops which are operational loops, an operational loop being a loop in which the respective branching conveyor, return conveyor and processing module are all fully operational, where X is an integer greater than 1;
iii) commencing a set-up phase by commencing to convey the plurality of unprocessed workpieces to the input in a sequential fashion, and thereafter onto the main conveyor line;
completing the set-up phase by diverting workpieces from the main conveyor line so that iv) each operational loop has at least one workpiece located thereon;
v) commencing an operational phase comprising controlling the branching conveyors so that each branching conveyor diverts every Xth workpiece received at that respective branching conveyor away from the main conveyor line to its respective operational loop;
vi) processing workpieces received at respective processing modules;
vii) returning the processed workpieces to the main conveyor line; and
viii) conveying the processed workpieces to the output.
